(19) United States
(12) Patent Application Publication
(10) Pub. No.: US 2026/0050177 A1
(43) Pub. Date: Feb. 19, 2026

(54) BINARY, FOURIER DOMAIN-SYNTHESIZED GRATINGS FOR MULTIPLE WAVELENGTH REFLECTORS

(71) Applicant: Quintessent Inc., Goleta, CA (US)

(72) Inventors: Szilard SZOKE, Los Angeles, CA (US); Michael Lawrence BELT, Goleta, CA (US); Justin Colby NORMAN, Goleta, CA (US); Michael DAVENPORT, Goleta, CA (US)

(21) Appl. No.: 19/295,502

(22) Filed: Aug. 8, 2025

Related U.S. Application Data
(60) Provisional application No. 63/682,562, filed on Aug. 13, 2024.

(51) Int. Cl. G02B 27/42; G02B 5/18; H01S 5/026

(52) U.S. Cl. CPC G02B 27/4272; G02B 5/1847; G02B 5/1871; G02B 27/4266; H01S 5/026; G02B 2005/1804

(57) ABSTRACT

A binary Fourier grating for producing a specified spectral response includes a plurality of grating superstructures disposed sequentially adjacent with respect to one another along a propagation direction of a light signal. Each of the grating superstructures have sequential sections with alternating refractive indices and one or more phase shift sections in which the refractive index does not alternate. A location of the one or more phase shift sections determines reflections at specified wavelengths and suppression of reflections outside of the specified wavelengths and a length of the grating superstructure determines a wavelength spacing between the specified wavelengths to thereby produce the specified spectral response.

### CROSS REFERENCE TO RELATED APPLICATION

This application claims the benefit of U.S. Provisional Application No. 63/682,562. The contents of the provisional applications noted above are incorporated herein by reference.

### BACKGROUND

Comb lasers with an arbitrarily adjustable number of comb lines and comb spacing configurations can be used in stand-alone lasers or in lasers integrated with silicon photonics circuits, including modulators, light splitters/combiners, filters, and photodetectors. Such multiwavelength sources are essential for applications in wavelength-division multiplexing (WDM) systems, optical signal processing, and quantum information systems, where precise control over the spectral properties of the laser output enables high system scalability and performance.

While the design of multiwavelength comb lasers can be approached using different methods, highly integrated solutions ultimately benefit from the use of gratings to obtain the reflection and feedback required for lasing to occur. However, the synthesis of gratings with optimal responses is either difficult to achieve, or the generated designs end up being inherently difficult to manufacture.

Conventional grating designs, include WSGs (windowed sampled gratings (WSGs), BSGs (Binary Superimposed Gratings), phase gratings (PGs), sampled gratings (SGs), super-structure gratings, (SSGs) and sampled interleaved gratings (SIGs). Each of these grating designs will be briefly described below.

A WSG is synthesized by configuring a Bragg grating such that the grating strength (and possibly the pitch) varies along the longitudinal axis of the structure. In this way, the propagating mode in the grating experiences a variation in the effective reflection strength. This tailoring of the reflection strength enables the generation of a comb-like spectral response. The underlying building blocks of the WSG are gratings represented by pure sinusoids, with the total number of sinusoids matching the desired number of comb lines. These sinusoidal gratings are then added together to create a complex grating profile. The spectral response of this profile can be further improved by applying a window function, which enhances the suppression of side modes. While the WSG provides the most ideal representation of the physical structure required to produce a desired comb-like response, it has some disadvantages. The need to vary the grating strength ultimately results in the effective grating strength being lower than that of a standard grating with fixed strength. Consequently, a longer grating is required to achieve a given reflectivity, which can be a limitation in some applications. Additionally, the variations in grating tooth offsets and pitches can make certain manufacturing approaches challenging, and given the many degrees of freedom in the grating profile, the WSG can be susceptible to fabrication imperfections and errors. Examples of WSG designs are described in co-pending U.S. application Ser. Nos. 17/465,403 and 17/697,199.

A BSG is constructed by first defining the grating as a superposition of sinusoidal gratings, with pitches chosen to correspond to the desired frequency peaks. The resulting analog grating profile is then quantized into a binary sequence using a thresholding or similar algorithm that converts each analog point into a 1 (grating tooth) when above a threshold value, or a 0 (grating gap) when below it. The sampling period is selected to be much smaller than the basic pitch of the grating (i.e., the sum frequency). This method has two undesired properties. First, the analog-to-digital conversion inherently results in a loss of information, leading to a distortion of the ideal response. Second, the choice of a very fine sampling periodicity results in a grating with extremely small features, making it exceedingly difficult to manufacture. An example of a BSG design is described in “Design of widely tunable semiconductor lasers and the concept of binary superimposed gratings (BSGs),” IEEE J. Quantum Electron., vol. 34, pp. 729-741, April 1998.

The PG follows a synthesis process identical to that of the BSG, where an analog grating profile is first generated via the superposition of sinusoidal gratings. A subsequent quantization step then transforms the analog profile into a binary sequence. In contrast to the BSG, however, the sampling period for the PG is chosen to match the pitch of the basic single-wavelength grating at the comb's center wavelength, making it easier to fabricate. To tailor the spectral response of the grating, the phase terms of each component sinusoidal grating are adjusted through numerical optimization to modify the interference pattern and, consequently, the envelope of the resulting analog grating profile. Phase shift locations are identified at the positions where the envelope of the interference pattern crosses zero. After discretization into binary form, the comb will not be flat, requiring an optimization step with many degrees of freedom in order to adjust the phase of the sinusoids to modify the interference pattern to make a flat comb. The number of phase shifts cannot be set by the grating designer, and the optimization must be performed on the full length of the grating because the spectral results would not scale in predictable ways if the grating were optimized in separate pieces. The major disadvantages of this grating type are, once again, the undesired and detrimental information loss resulting from the analog-to-digital conversion, as well as the numerically complex optimization process required to determine the optimal sinusoidal phase shift values. An example of a PG design is described in Realization of Phase Grating Comb Reflectors and Their Application to Widely Tunable DBR Lasers, IEEE Photonics Technology Letters, 16(11), 2427-2429. doi:10.1109/lpt.2004.834887.

Conceptually, the SG is perhaps the simplest method for obtaining a comb-like grating response. It involves modulating a uniform Bragg grating to generate bursts of grating separated by regions with no grating. This modulation produces a characteristic comb spectrum with a distinct sinc-function-like envelope. The shape of this envelope is directly tied to the lengths of the grating bursts, making the SG often undesirable in applications requiring broadband, flat-top comb spectra. This is due to the loss of effective grating strength and the lower reflection levels observed at the edges of the spectrum. An example of an SG design is described in Tunable Sampled-Grating DBR Lasers with Integrated Wavelength Monitors, IEEE Photon. Technol. Lett., vol. 10, pp. 1085-187 August 1998.

The SSG is a technique used to synthesize highly flat-top, uniform comb spectra. This method relies on modifying a regularly periodic Bragg grating (analogous to the uniform binary Bragg grating but with a length not set by any grating superstructure) section by section, applying a chirp to each segment. Using numerical optimization techniques, a set of grating segment lengths and chirp values can be identified to generate the desired comb-like behavior. From a manufacturability standpoint, the SSG is very challenging to fabricate. The fine changes in grating pitch are difficult to achieve, even with e-beam lithography, and are therefore challenging to scale. An example of an SSG design is described in Quasicontinuous Wavelength Tuning in Super-Structure-Grating (SSG) DBR Lasers, IEEE J. Quantum Electron., vol. 32, pp. 433-441, March 1996.

The SIG is formed from a unit cell consisting of two sampled gratings with phase shifts between and after them. The length of the unit cell sets the frequency spacing of the resulting comb, while the lengths of each sampled grating within the unit cell can be adjusted to achieve a desired spectral envelope over the wavelength range of interest. A key advantage of this approach is its manufacturability, as the grating is simple to fabricate due to its binary nature and the small fill factor of the unit cell typically used to obtain flat-top reflectivity spectra. The small fill factor reduces write time for e-beam lithography; however, it comes at the cost of reduced maximum grating strength. A further disadvantage of the SIG is its tendency to exhibit relatively poor SMSR due to its sinc-function-like roll-off, an issue avoided in the present approach by incorporating additional grating sections. An example of SIG is described in Novel Interleaved Sampled Grating Mirrors for Widely Tunable DBR Lasers, IEE Proceedings, online no. 20010104. DOI: 10.1049/ip-opt:20010104.

### SUMMARY

In one aspect, a grating design methodology is described herein that enables the synthesis of completely binary grating structures with arbitrarily adjustable comb-like reflection spectra. In contrast to other binary grating designs, the Binary Fourier-domain Synthesized Grating (BFG) described herein facilitates the creation of gratings with high reflectivity, low insertion loss, optimal comb flatness, high comb spacing accuracy, and significant rejection of side modes outside the desired comb bandwidth. Furthermore, the designs are easy to fabricate due to the inherent structure of the BFG, which consists of a simple on/off grating with no variation in grating feature amplitudes or offsets to tailor the grating strength. The grating's wavelength-dependent response (e.g., comb-like behavior) is determined entirely by a set of N “phase-shift” locations. At these positions, a quarter-wave phase shift is introduced into the grating periodicity, effectively flipping the polarity of the grating. The phase-shift locations are determined through numerical optimization, with the BFG uniquely establishing an optimization problem with orders of magnitude fewer degrees of freedom than any comparable binary system. As a result, the problem can be solved efficiently and rapidly.

In contrast to existing methods for synthesizing grating profiles with a desired response, the BFG is designed entirely in the binary domain. With most other grating types, the design approach begins by synthesizing an analog grating profile using a set of N sinusoidal basis functions that represent the individual Bragg periodicities required to create reflections at N different wavelengths. Following this, digital signal processing methods are employed to transform the analog grating profile into a digital one. This step inherently distorts the response of the original ideal grating, and such distortions are difficult to remedy. Consequently, the resulting grating often suffers from uneven comb line amplitudes, shifts in comb spacing, and an implementation of a suboptimal number of phase-shift locations, all of which contribute to higher than necessary insertion loss.

Compared to other binary grating designs synthesized directly in the binary domain (commonly referred to as “aperiodic gratings”), the BFG offers a computationally much simpler synthesis approach, significantly lower insertion loss, and more straightforward fabrication due to its predominantly regular binary sequence. This last point highlights a key disadvantage of aperiodic gratings: while they allow highly customizable spectral responses, their highly irregular sequences generate substantial losses in the propagating modes, making them less desirable for many practical applications.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Furthermore, the claimed subject matter is not limited to implementations that solve any or all disadvantages noted in any part of this disclosure.

### BRIEF DESCRIPTION OF THE DRAWINGS

FIGS. 1A-1F depict the conventional methodology for designing a grating that produces a comb spectrum.

FIG. 2 is a graphical representation of the conventional grating design methodology illustrated in FIG. 1.

FIGS. 3A-3F depict the grating design process of the present disclosure.

FIG. 4 is a graphical representation of the grating design process of the present disclosure.

FIG. 5A shows the spatial representations of the uniform binary Bragg grating;

FIG. 5B shows the spatial representation of the modulation function; FIG. 5C shows the spatial representation of the resulting final Binary Fourier-domain Synthesized Grating (BFG) after multiplication of the gratings shown in FIGS. 5A and 5B.

FIG. 6 shows the Fourier coefficients that are calculated and optimized for 100 GHz intervals, thereby enabling the generation of a 200 GHz comb spacing.

FIG. 7A shows the physical structure of one example of an optimized BFG; FIG. 7B shows the corresponding spectral response.

FIG. 8A shows the physical structure of one example of a cavity phase shift function; FIG. 8B shows the corresponding spectral response. FIG. 8C shows the physical structure of an optimized 4 wavelength BFG, with an additional defect mode implemented to facilitate its use as a DFB laser; FIG. 8D shows the corresponding spectral response.

FIGS. 9-14 shows various illustrative physical implementations of a BFG.

### DETAILED DESCRIPTION

### Definitions

As used herein, grating strength refers to the difference in the effective index of refraction of a grating tooth and a grating gap, which, together with the grating length, quantifies the feedback provided by a periodic refractive-index modulation.

As used herein, grating unit cell refers to a periodic Bragg grating burst that produces a reflection at a specific wavelength and with a specific bandwidth depending on its grating pitch, grating strength, and length.

As used herein, grating modulation function refers to a function that determines how the phase of a grating is shifted along its length to generate a desired comb wavelength spectrum.

As used herein, uniform binary Bragg grating (UBB) refers to a Bragg grating of uniform grating pitch along its length, with a length corresponding to the desired wavelength spacing, and a grating pitch that determines the wavelength centering of the final grating's reflection wavelength spectrum.

As used herein, grating superstructure refers to the spatial domain multiplication of the UBB and grating modulation function, having a spatial length of one grating modulation function section (and one UBB) and a wavelength spectrum that is the convolution of the grating modulation function spectrum and UBB spectrum.

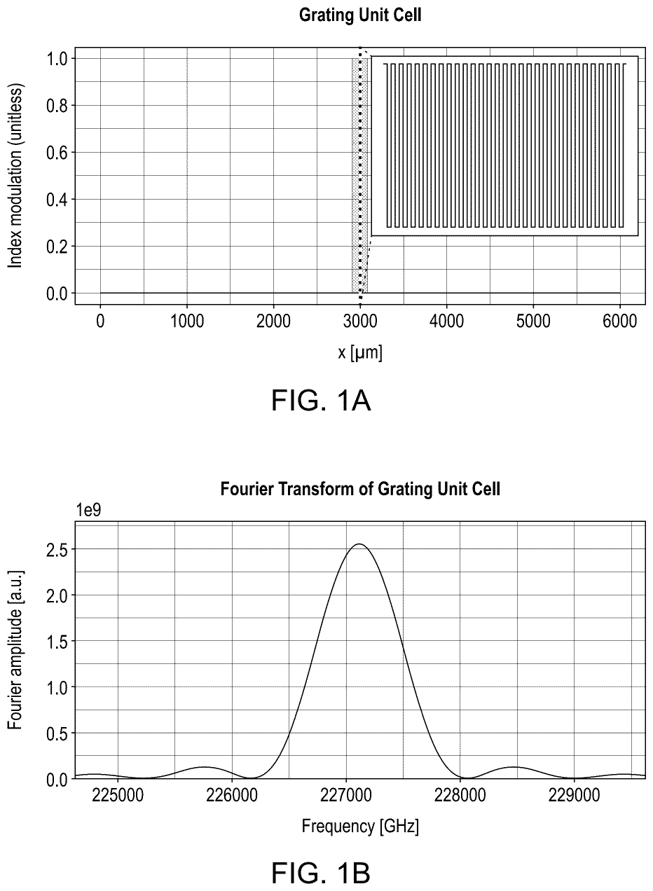

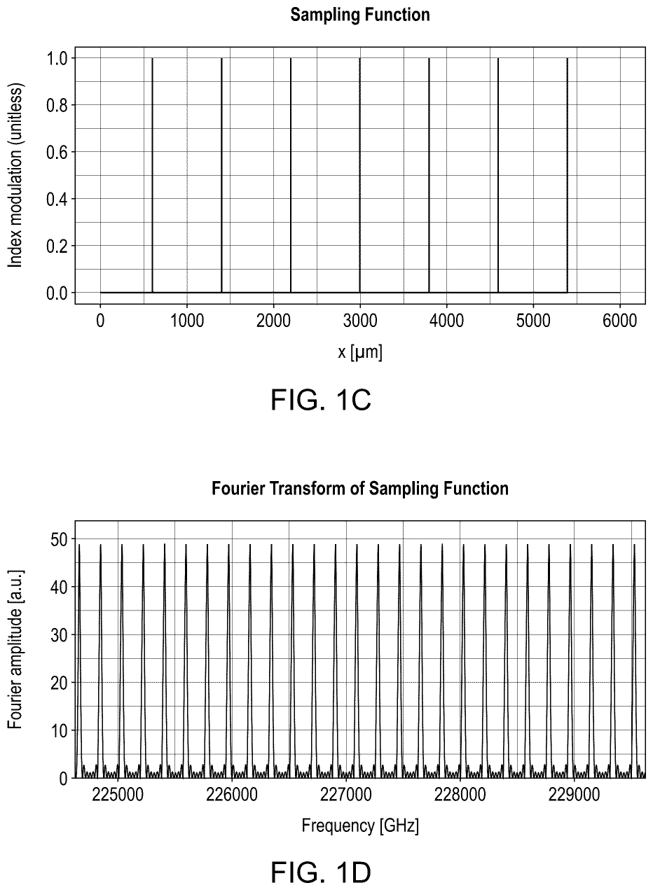

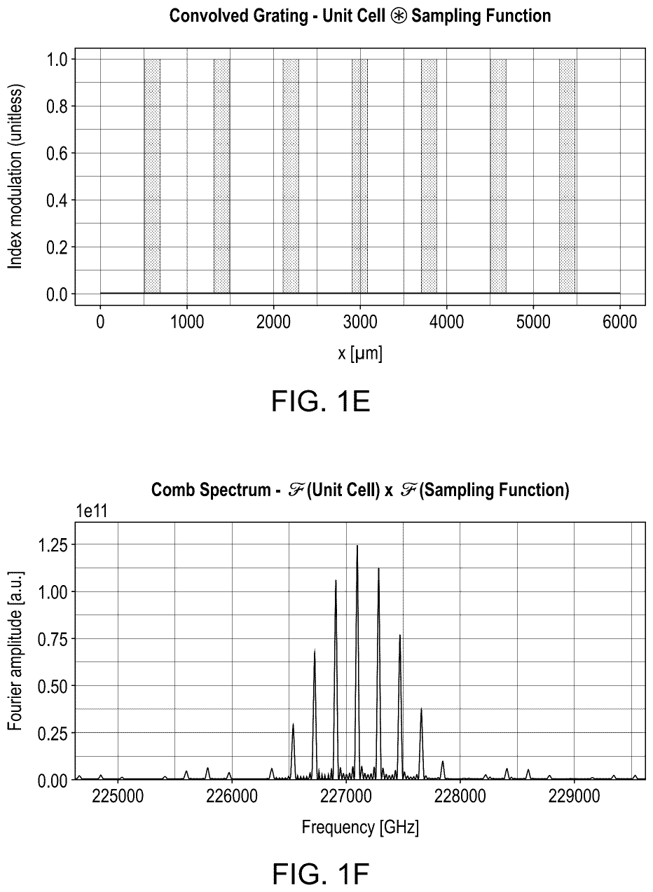

FIG. 1 shows the conventional methodology for designing a grating that produces a comb spectrum. This approach relies on the convolution theorem, which states that convolution in the spatial domain corresponds to multiplication in the frequency domain, and vice versa. That is, given two grating with spatial structures f₁(x) and f₂(x) and having Fourier transforms F₁(k) and F₂(k), respectively, convolving the Fourier representations yields:

$${f}_{1} ( x ) * {f}_{2} ( x ) = {F}_{1} ( k ) \times {F}_{2} ( k )$$

where * denotes convolution.

The Fourier transform F(k) represents the frequency response of a grating structure having the corresponding spatial structure f₁(x).

Referring now to FIG. 1, FIG. 1A shows the spatial representation of a periodic grating that is here referred to as a unit cell, which produces the Fourier transform shown in FIG. 1B. FIG. 1C shows the spatial representation of a periodic grating referred to as a sampling function, which produces the Fourier transform shown in FIG. 1D. Finally, FIG. 1E shows the convolved grating resulting from the convolution of the unit cell and sampling function gratings shown in FIGS. 1A and 1C and FIG. 1F shows the multiplication of the Fourier representations shown in FIGS. 1B and 1D.

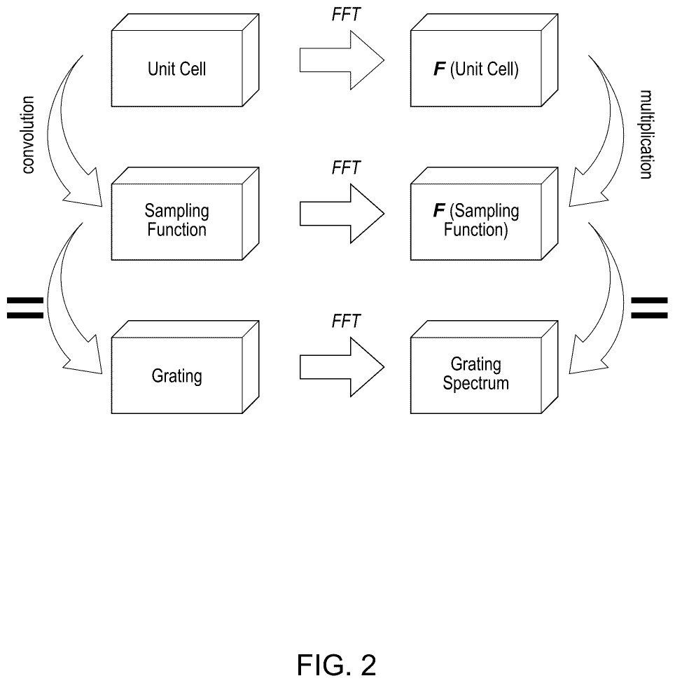

FIG. 2 is a graphical representation of the conventional grating design methodology illustrated in FIG. 1.

Thus, the conventional methodology depicted in FIGS. 1 and 2 results in the unit cell spectral response being repeated at regular intervals. This methodology shows an approach to grating design that divides the grating synthesis into two component parts, the unit cell and the sampling function. This is relatively straightforward to model and can be used to construct the physical structure of the desired grating that yields the spectral response shown in FIG. 1F.

The grating design methodology depicted in FIGS. 1 and 2 is well suited for synthesizing complex grating responses. However, a significant flaw arises when flat, finite-bandwidth, comb-like spectra are desired, whereby the physical grating efficiently utilizes the total available space, such that the grating strength is maximized. This is because to obtain the desired comb shapes, the spectral response of the unit cell is required to be highly rectangular. This type of spectral shaping is only possible through distinctly aperiodic binary sequences, which consequently lead to highly disordered unit cell gratings. Such gratings are characterized by high propagation losses of the modes encountering the structure as a result of the Bragg condition only being partially satisfied.

In accordance with present disclosure, the above design methodology is reformulated using the inverse of the convolution theorem described above. This design process is referred to herein as the Binary Fourier-Domain synthesized Grating (BFG) synthesis process. In particular, the inverse convolution theorem that is employed herein is:

$${f}_{1} ( x ) \times {f}_{2} ( x ) = {F}_{1} ( k ) * {F}_{2} ( k )$$

That is, multiplication in the spatial domain corresponds to convolution in the frequency domain.

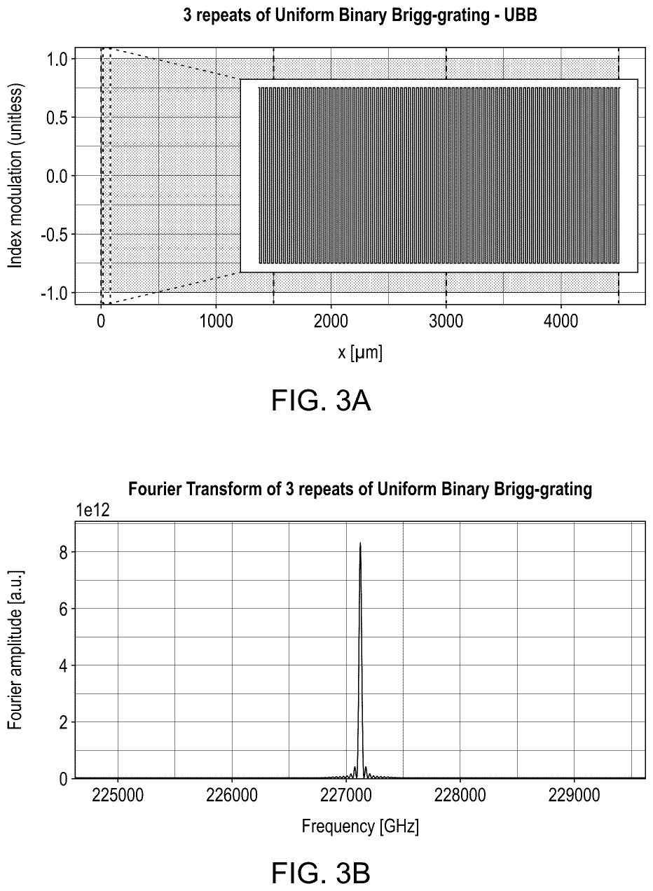

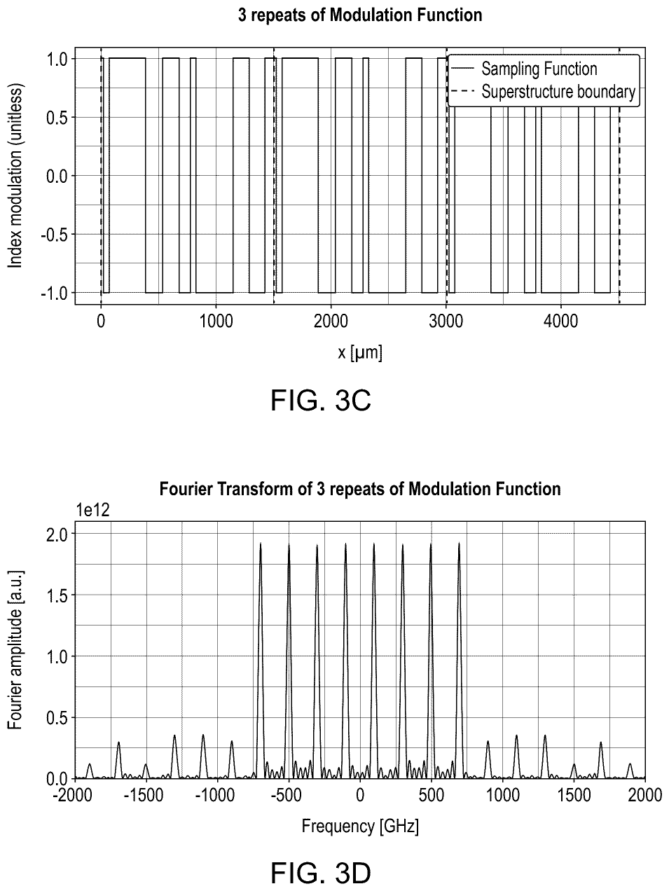

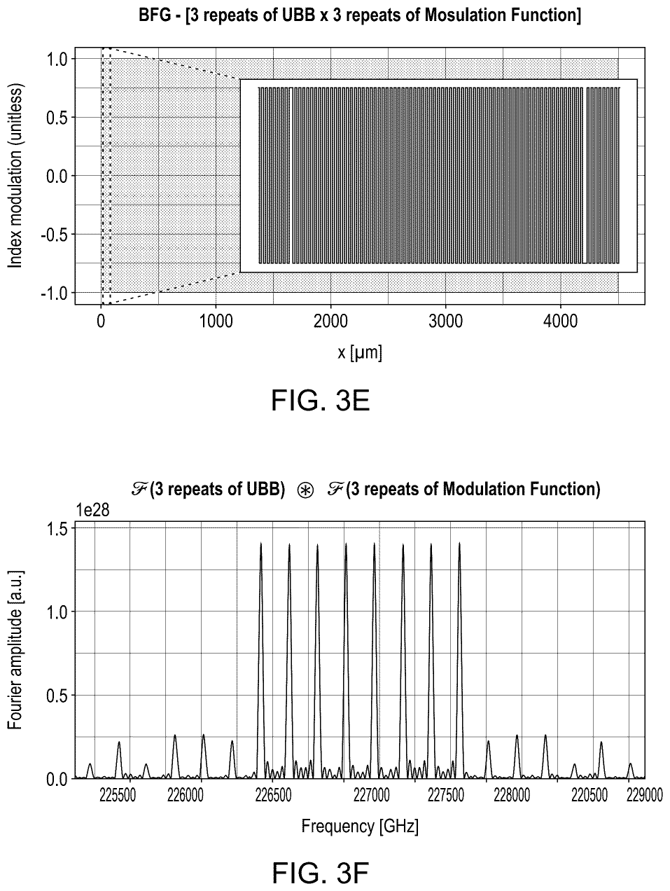

The BFG design process is illustrated in FIG. 3 for the design of an 8-line comb. FIG. 3A shows the spatial representation of uniform binary Bragg-gratings (UBBs), which produces the Fourier transform shown in FIG. 3B. The Fourier transform of UBBs is shown in FIG. 3B, which represents the spectral response of UBBs, displays the characteristic sinc-like behavior. FIG. 3C shows the spatial representation of a modulation function (with three repetitions), which produces the Fourier transform shown in FIG. 3D. The modulation function inverts the polarity of the regular periodicity uniform binary Bragg grating at specific locations, thereby tailoring the spectral response so that it displays the comb-like response it was optimized to produce. FIG. 3E shows the spatial representation of the grating that results from the multiplication of the uniform binary gratings shown in FIG. 3A with the spatial representation of the modulation function sections shown in FIG. 3D. The resulting final structure shown in FIG. 3E is referred to herein as the BFG, which is composed of multiple grating superstructures. In this example figure there are 3 superstructures (corresponding to 3 repetitions of the modulation functions and 3 UBBs) included as indicated in FIG. 3C, and the full BFG grating is composed of these 3 superstructures repeated sequentially. FIG. 3F shows the convolved BFG spectrum resulting from the convolution of the Fourier representation of the uniform binary gratings shown in FIG. 3B with the Fourier representation of the modulation function shown in 3D. Although the spectral responses in FIG. 3D and FIG. 3F look similar, it is important to note that the spectrum in 3D is centered around 0 Hz and requires convolution with the high frequency component of 3B (resulting from the physical structure in 3A) to shift the 3D spectrum to the desired frequency obtained in 3F.

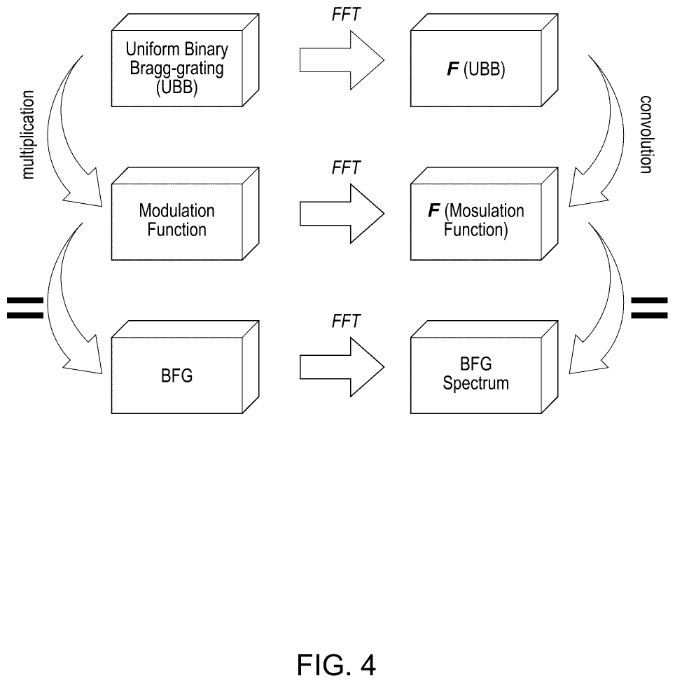

FIG. 4 is a graphical representation of the BFG design process illustrated in FIG. 3.

The BFG design process allows for a uniform binary grating to be used as the starting point, which is known to be a low disorder, low loss design, since the Bragg condition is fully satisfied along the entire length of the grating. The objective now is to obtain a modulation function which has a Fourier domain response that resembles an apodized comb shape. Therefore, the component parts of the resulting grating are the uniform binary grating, which produces a single sinc function-like response at a specific frequency, and the modulation function which repeats and modulates this single sinc function in the form of a comb.

Finding the desired modulation function is a straightforward and computationally efficient process. As the Fourier transform of a Dirac comb is another Dirac comb, the modulation function should be reminiscent of a displaced set of comb lines. The displacement enables the suppression or amplification of certain comb lines to occur. Therefore, rather than ending up with an equal amplitude comb in the Fourier domain, it is possible to obtain a frequency response in the form of an apodized comb. The choice of basis for the modulation function is of some practical significance. A [−1,1] basis is used throughout the synthesis of the BFG for two reasons. One, it enables the multiplicative operation in the real domain to be valid. As a consequence, the binary sequence that is obtained after multiplication makes physical sense, whereby multiplication with 1 leaves the part of the regular grating unchanged, and multiplication with −1 introduces an inversion in the polarity of the sequence. This makes the locations of the critical phase shifts directly associated with transitions of the modulation function. The second reason for this choice of basis is that it eliminates any DC frequency components from the Fourier transform of the modulation function, due to the amplitude variations being centered about 0. More generally, however, any suitable basis may be chosen.

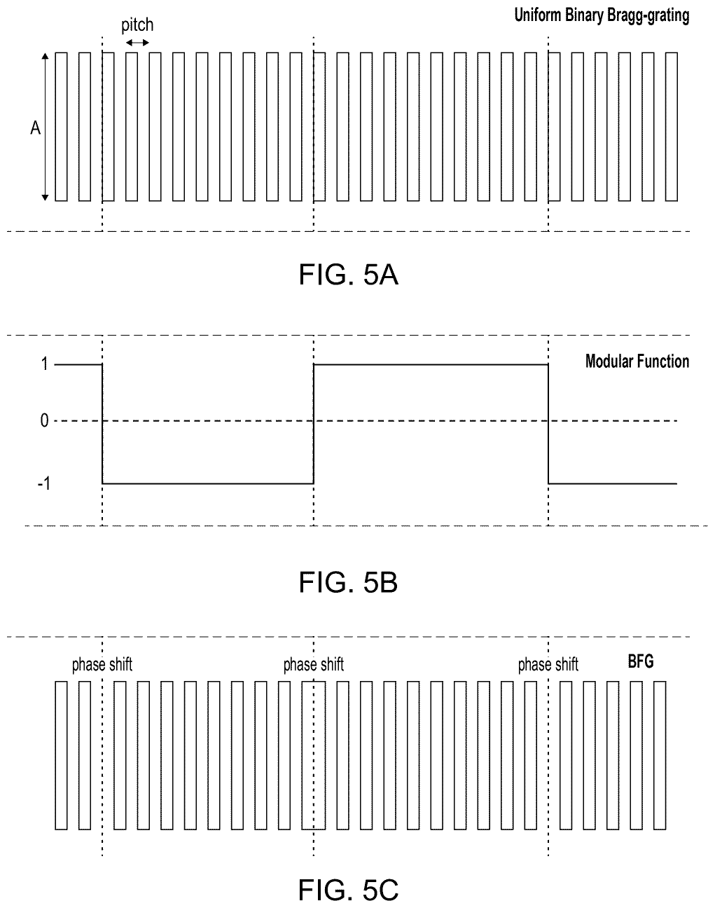

FIG. 5A shows the spatial representation of a section of the uniform binary Bragg grating, which is used as the starting point of the BFG synthesis process. FIG. 5B shows the spatial representation of the modulation function which has the same length as the uniform binary Bragg grating shown in FIG. 5A. FIG. 5C shows the spatial representation of the resulting final BFG grating after multiplication of the gratings shown in FIGS. 5A and 5B. The resulting final BFG grating shown in FIG. 5C corresponds to a small section of the BFG shown in FIG. 3E.

As FIG. 3 illustrates, the Fourier response of the modulation function is directly imprinted onto the final comb structure shown in FIG. 3F. Therefore, the BFG synthesis process simply involves tailoring the number and amplitudes of comb lines produced by the modulation function. This process can be accomplished in a straightforward and fast manner since it only requires a limited number of comb lines (which correspond to the transitions in the spatial representation of the modulation function) in the spatial domain to achieve N lines in the frequency domain. The number of phase shifts required per grating superstructure is directly tied to the plurality of comb lines desired, how much tailoring the actual spectral response requires, as well as if the comb has an even or an odd number of lines. In most situations, a sufficient number of phase shifts may be close to twice the number of comb lines. Fewer phase shifts allow for a reduction in perturbations; however, it also restricts the amount of side mode suppression that is possible to achieve. Additional phase shifts can enable better suppression of the side modes, at the expense of a more aperiodic grating which has more optical loss.

Furthermore, the allowable comb line spacing (the frequency spacing between reflection peaks) is entirely determined by the length of the modulation function's spatial representation. Therefore, the length of the superstructure itself (shown in FIG. 3C) directly dictates the accessible Fourier coefficients that are supported. This means that the resolution of the Fourier transforms during the optimization process can be reduced to their absolute minimum, where only Fourier coefficients that are located at integer intervals of the supported comb spacing are required to be calculated. This is in stark contrast to the aperiodic grating synthesis method depicted in FIGS. 1-2, which requires extremely high-resolution Fourier transforms, making the optimization problem even challenging for GPU based algorithms. On other hand, the BFG optimization process can be performed on typical desktop/laptop CPUs with less than one minute runtimes. Even and odd comb number configurations are easily obtained by carefully considering the zero-frequency Fourier coefficient and the respective frequency spacing between the other coefficients.

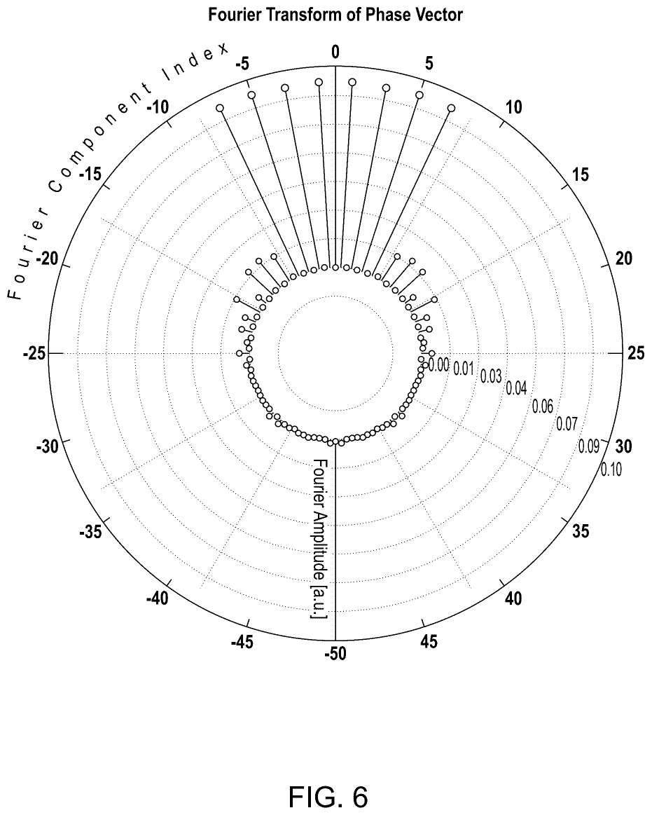

FIG. 6 shows the final output of an optimization run, whereby the Fourier coefficients are calculated and optimized for 100 GHz intervals, thereby enabling the generation of a 200 GHz comb spacing. For generality, the Fourier coefficient index is used instead of a frequency axis. The suppression of all even integer multiples of the 100 GHz sampling interval leads to the creation of an even number comb design with 200 GHz comb spacing. Of particular importance is that odd number comb designs allow for the sampling interval to be twice that of the even number comb case, thereby enabling the use of superstructures with half the length. This is due to the reciprocal relationship between superstructure length and the minimal required sampling interval.

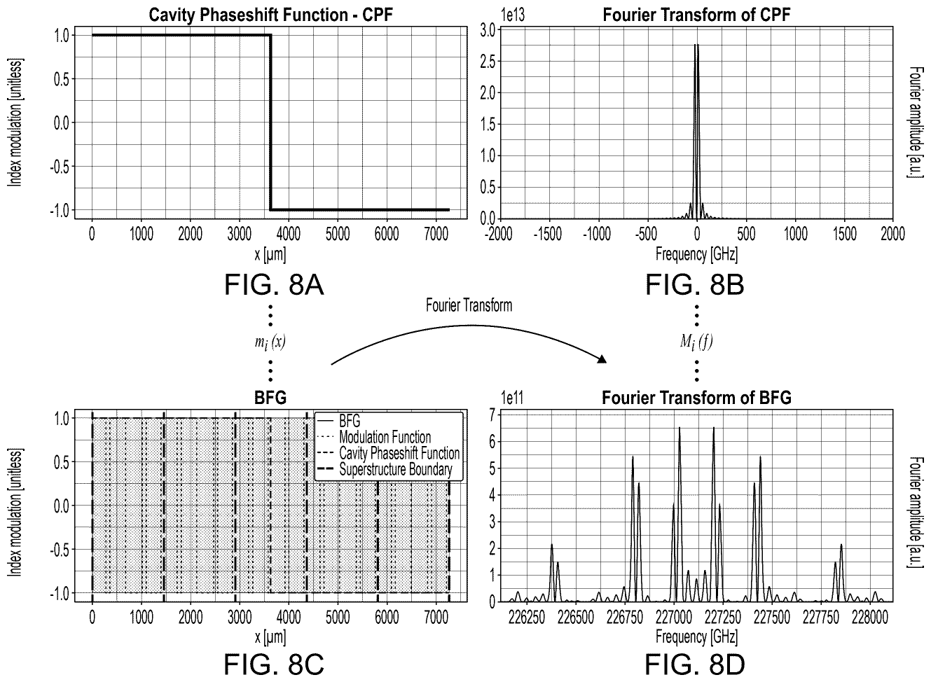

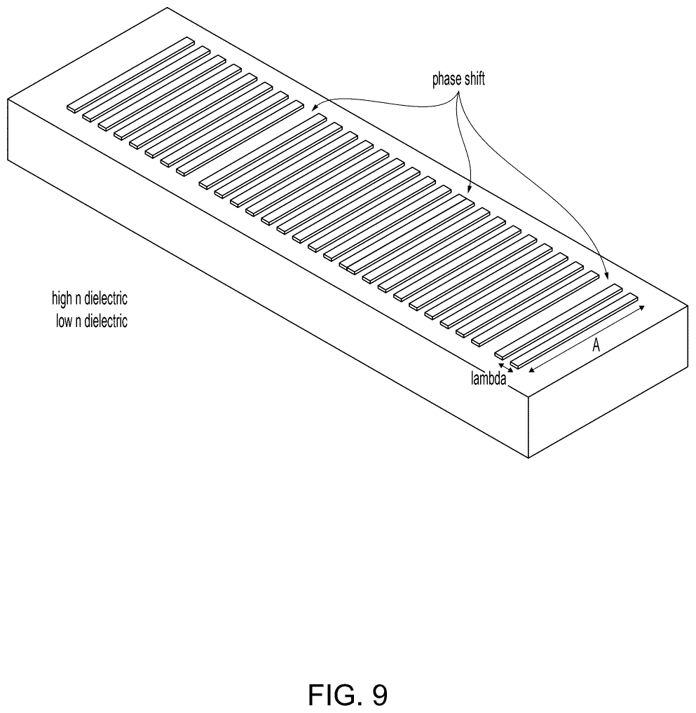

Repeating the synthesized superstructure is straightforward, with the primary consideration being the polarity of the tooth at the start and end of the superstructure. These should be opposite (i.e., starting with a tooth and ending with a gap, or vice versa) to prevent unwanted resonances caused by additional phase shifts at the interfaces between superstructures. The number of superstructure repetitions plays a critical role in shaping the final spectrum. Beyond increasing the effective grating strength and, consequently, the total reflectivity, additional repetitions reduce the linewidths of the comb resonances through long-range constructive and destructive interference. Moreover, gratings with a greater number of repetitions exhibit improved comb flatness, as all wavelengths experience equal effective grating strengths along the propagation length. Asymmetric BFG-based DFB laser architectures can deliberately employ a different number of superstructures on either side of the cavity phase-shift function's central point (see FIG. 8). Such asymmetric DFB laser designs are of importance when preferential emission of the lasing power towards one side should take place. Additionally, if the total length of the laser should be kept constant, an asymmetric design can be implemented by adjusting the grating strength of the superstructures to be uneven on either side of the cavity center.

Owing to the inherent linearity of both the time-domain and frequency-domain operations—specifically, multiplication in the real domain and convolution in the spectral domain—the BFG framework can be straightforwardly generalized to accommodate an arbitrary number of cascaded elemental functions. In practice, this means that a complex overall reflection or transmission response can be decomposed into a series of simpler “building-block” gratings, each characterized by its own modulation function [mᵢ(x), mⱼ(x), mₖ(x), . . . ] and corresponding Fourier transform [Mᵢ(f), Mⱼ(f), Mₖ(f), . . . ]. By convolving these component spectra in series, one obtains the total spectral response:

$${R}_{\{ total \}} ( f ) = {M}_{\{ 1 \}} ( f ) * {M}_{\{ 2 \}} ( f ) * … * {M}_{\{ N \}} ( f )$$

where “***” denotes convolution.

This modular approach is especially powerful in the design of cavity responses for distributed-feedback (DFB) lasers employing BFG reflectors. Inserting an additional pair [{mᵢ(x), Mᵢ(f)}, {mⱼ(x), Mⱼ(f)}, {mₖ(x), Mₖ(f)}, . . . ] into the cascade introduces a localized spectral “defect” or cavity mode at a user-defined frequency. Because each modulation function mim_imi may be assigned an arbitrary amplitude and phase-shift profile, the resulting defect mode can be shaped with fine spectral precision—whether that entails a single discrete phase-shift element at the center of the grating or a distributed pattern of small, incremental phase steps across multiple grating elements.

By leveraging this linear-cascade decomposition, one can explore a broad design space of unconventional phase-shift sequences—beyond the classic quarter-wave shift—without sacrificing generality or increasing implementation complexity. Simple cavity implementations (e.g., a single π-phase shift) and more elaborate, multi-section phase distributions can both be modeled, analyzed, and optimized within the same BFG framework. As a result, the BFG is well suited for engineering arbitrary spectral defects in lasers, enabling precise control over lasing wavelengths, mode spacing, and side-mode suppression in advanced DFB devices.

FIG. 8 shows the generalized framework with the additional implementation of a simple, single quarter-wave phase shifted cavity design as an additional modulation function. FIG. 8A shows the modulation function which generates the sinc-shaped spectral response depicted in FIG. 8B, now with a defect mode present. FIG. 8C and FIG. 8D show the resultant BFG grating, and its spectral response as obtained via a Fourier transform respectively. The final BFG spectrum now has the defect mode imprinted on it as a result of the convolution with the cavity phase shift function's spectral response.

### Analytical Formulation of the BFG

Using the convolution theorem and linearity of the Fourier transform, an analytical equation can be derived to obtain the coupling constant of an arbitrary BFG, which in turn can be used to calculate the grating's reflection spectrum using coupled mode theory. Since the modulation function can be represented as a sum of square waves, the Fourier transform can be represented as a sum of sinc functions with an additional phase term to account for the offset of the square waves with respect to each other. The equation for this is:

$$κ ( n ) = {κ}_{0} {\sum }_{ϕ = 0}^{{N}_{ϕ}} {Z}_{ϕ} sin c ( n π {Z}_{ϕ} ) exp ( - in {ψ}_{ϕ} )$$

Here, k₀ is the coupling constant at the Bragg wavelength if the grating were continuous, Z_{φ} is the location of phase shift φ given as a fraction of the total grating superstructure length, φ is an index counting up to the total number of phase shifts N_{φ}, n is a Fourier coefficient relating to a particular frequency, and Ψ represents the cumulative phase shift associated with each section of grating teeth and its subsequent phase shift section referenced to the start of the grating superstructure.

This equation provides a simple picture to illustrate the design principles of a BFG. The design degrees of freedom are the number of phase shifts and their position within the superstructure, keeping in mind that the superstructure length is explicitly fixed by the desired comb frequency spacing, center wavelength, and refractive indices of the grating materials. The coupling constant of each Fourier component is represented as a sum of sinc functions with their amplitudes and the full-width-at-half-maxima set by the position of each phase shift. The cumulative phase term then modulates the amplitude of the sinc peak between positive and negative values dependent on the spacing between phase sections, keeping in mind that all BFG phase shifts are π in length. The net effect is that phase shift positions are chosen to obtain sinc functions of varying width that are added and subtracted from each other in order to achieve the desired spectral envelope.

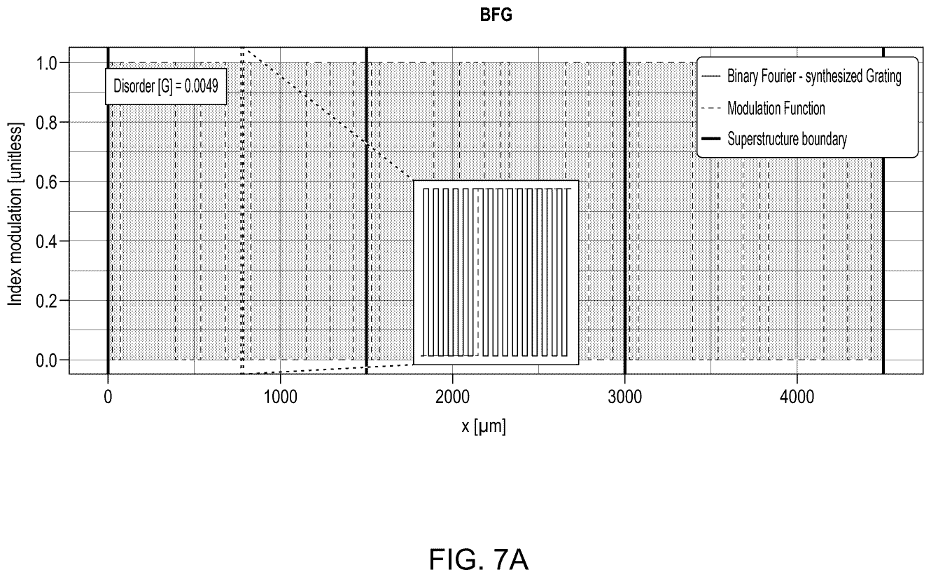

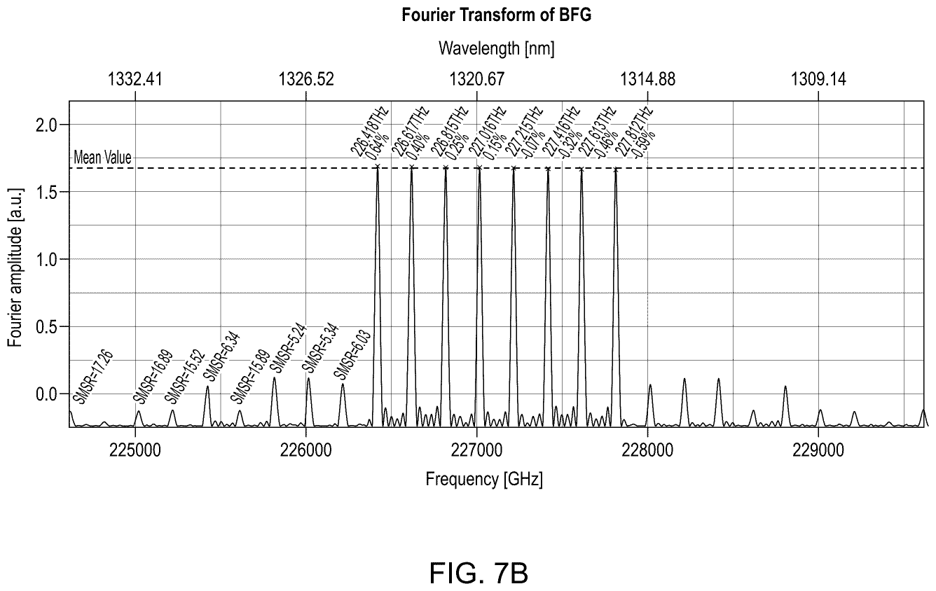

FIG. 7A shows the physical structure of one example of an optimized BFG and FIG. 7B shows its corresponding spectral response. In particular, FIG. 7A shows the physical layout of uniform binary Bragg gratings and the corresponding modulation function required to multiply with in order to create a BFG. In this example the modulation function is plotted using a basis of [0,1]. Of course, as previously mentioned, more generally any suitable basis may be chosen. The dashed lines delineate the superstructures, showing that the BFG is composed of 3 repeats of the same superstructure. This is also easily visible by observing the repetitions of the modulation function. FIG. 7B shows the corresponding Fourier transform (and therefore spectral response) of the BFG, with comb lines being labeled by their frequencies and percentage deviations relative to the mean value of the 8 comb lines. The side modes are labeled by their SMSR values.

### ILLUSTRATIVE EMBODIMENTS

BFGs can be physically implemented in a variety of ways. A binary grating is a type of periodic optical structure whose refractive index (or surface height) alternates along the propagation direction between two discrete values, typically “high” and “low.” That is, the structure has only two distinct levels (e.g., etched vs. unetched, or high index vs. low index), making it “binary” in nature.

The BFG may be physically realized in a number of different ways, including, for example, as surface-relief binary grating and index-modulated binary grating. In surface-relief binary grating, the structure alternates between two heights (e.g., etched trenches and unetched regions on a substrate). In index-modulated binary grating, the structure alternates between two refractive indices within the waveguide or material.

A binary grating may have either a positive or a negative polarity structure. In the positive case, the grating features (i.e. the grating teeth) are a high refractive index material located on a low index material. In the negative case, the grating features are effectively etched into a high index material layer that is located on top of a low index material. Examples of various schemes for realizing the physical features of a BFG based on these structures are described below.

FIG. 9 shows a physical implementation of a BFG with a high refractive index dielectric that is patterned using a BFG binary sequence as determined by the techniques described above. The high refractive index dielectric is located on a low refractive index dielectric. The grating structure in this case simply consists of a tooth sequence, with the propagating light being guided by other layers/structures (not shown).

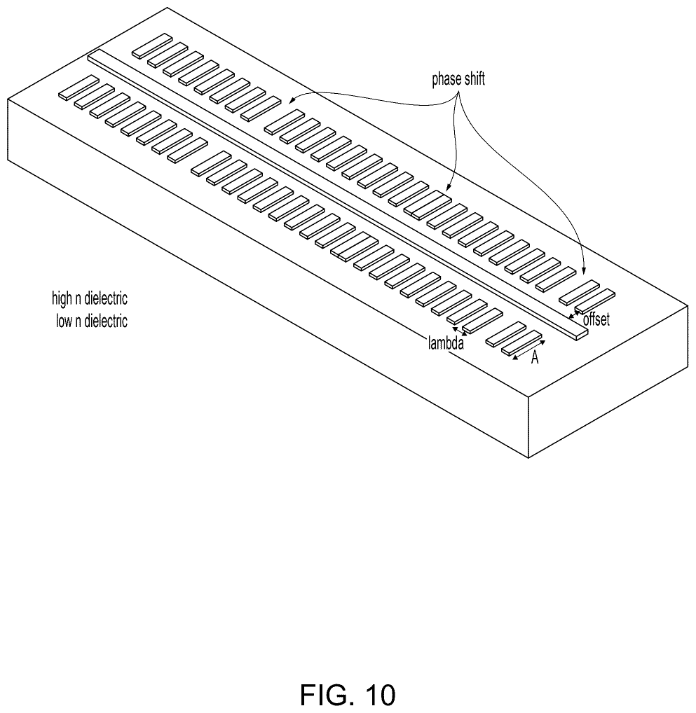

FIG. 10 shows a physical implementation of a BFG with a high refractive index dielectric that is patterned using an optimal BFG binary sequence, which is located on a low refractive index dielectric. In this case the grating structure consists of a central waveguide supporting the propagation of the guided modes, with the grating teeth being located on either side of the waveguide. The offset of the grating teeth positions relative to the central waveguide enables the tailoring of the strength of the reflection.

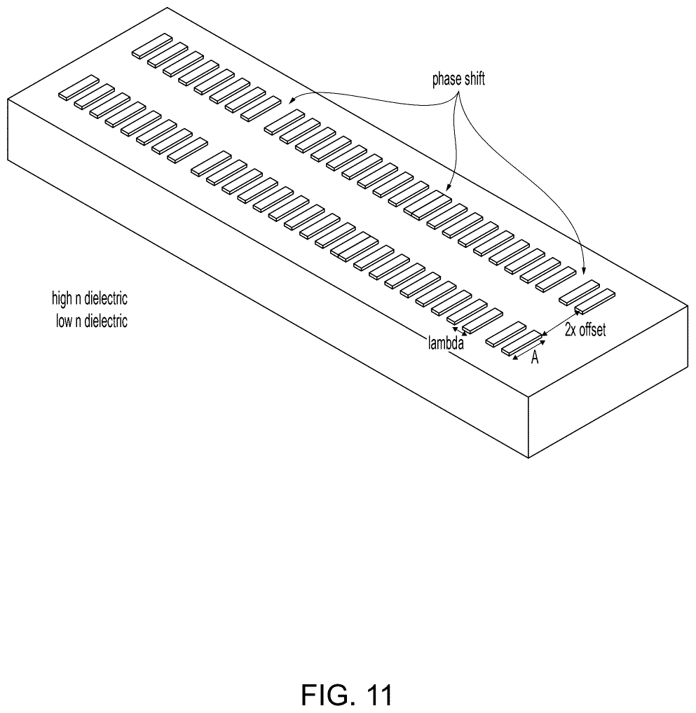

FIG. 11 shows a physical implementation of a BFG with a high refractive index dielectric that is patterned using the optimal BFG binary sequence, which is located on a low refractive index dielectric. In this case the grating structure consists of only the grating teeth, which are located on either side of a central symmetry-line. The offset of the grating teeth positions relative to the center line enable the tailoring of the strength of the reflection. The propagating light is assumed to be guided by other layers/structures (not shown).

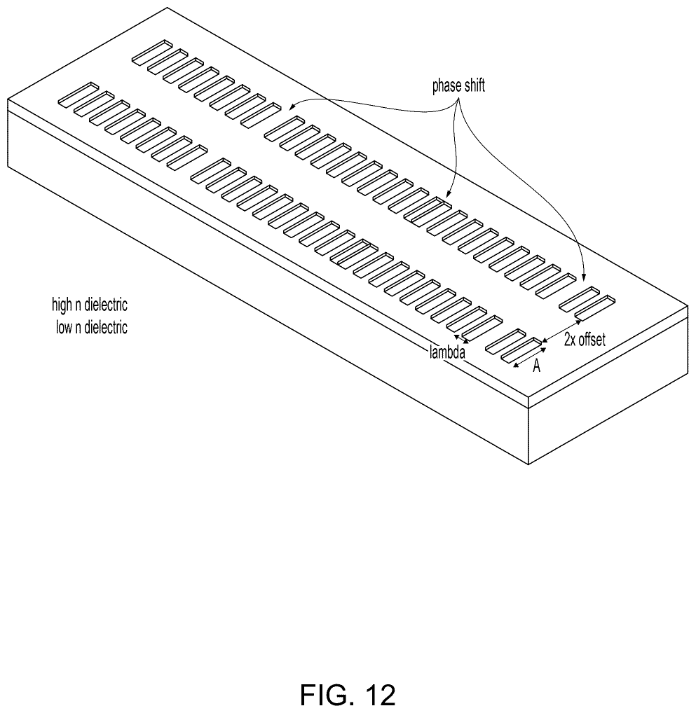

FIG. 12 shows a physical implementation of a BFG with a high refractive index dielectric that is patterned using an optimal BFG binary sequence, which is located on a low refractive index dielectric. In this case the grating structure consists only of the grating teeth, which are etched into the high refractive index dielectric layer. The effect of this change is to create a reverse polarity grating. The teeth are located on either side of a central symmetry-line. The offset of the grating teeth positions relative to the center line enable the tailoring of the strength of the reflection. The propagating light is assumed to be guided by other layers/structures (not shown).

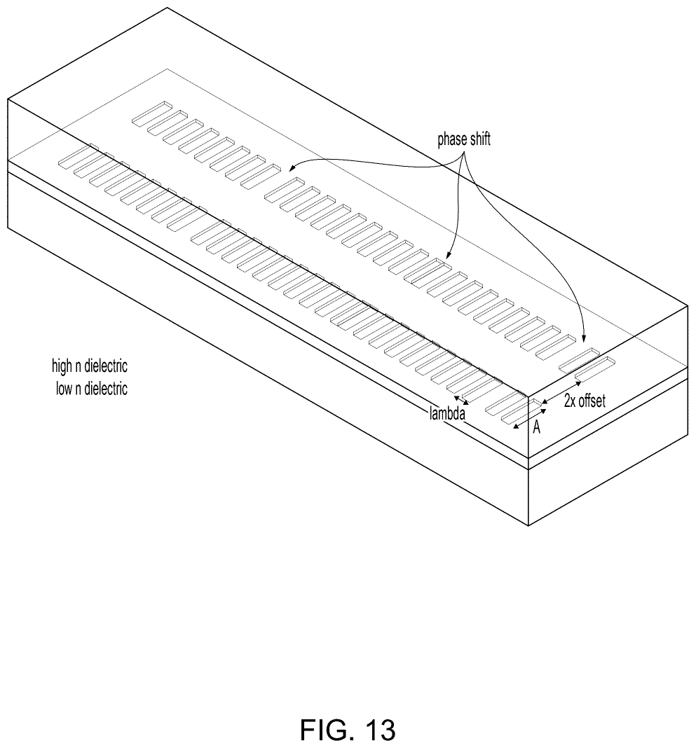

FIG. 13 shows a physical implementation of a BFG with a high refractive index dielectric that is patterned using an optimal BFG binary sequence, which is located on a low refractive index dielectric. In this case the grating structure in consists only of the grating teeth which are etched into the high refractive index dielectric layer. The effect of this change is to create a reverse polarity grating. The teeth are located on either side of a central symmetry-line. The offset of the grating teeth positions relative to the center line enables the tailoring of the strength of the reflection. On top of the high refractive index dielectric layer is an active gain material, which the propagating modes inside the grating structure interact with. The propagating light is assumed to be guided by other layers/structures (not shown).

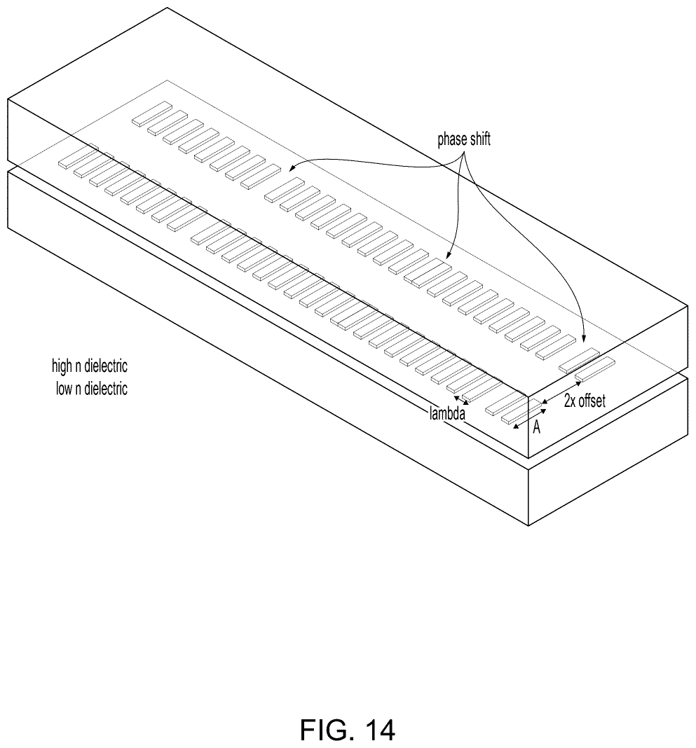

FIG. 14 shows a physical implementation of a BFG with a high refractive index dielectric being patterned using the optimal BFG binary sequence, which is located on a low refractive index dielectric. In this case the grating structure consists only of the grating teeth which are located on either side of a central symmetry-line. The offset of the grating teeth positions relative to the center line enables the tailoring of the strength of the reflection. An active gain material is located on the high refractive index dielectric layer has sitting on top of it an active gain material, which the propagating modes inside the grating structure interact with. The propagating light is assumed to be guided by other layers/structures (not shown).

Examples of some illustrative embodiments of a BFG in accordance with the present disclosure are presented below. In some cases the various embodiments may be combined with one another in any suitable combination to form additional embodiments.

In some embodiments, a BFG is placed adjacent to one side or both sides of an active material (gain medium) thus forming a laser cavity that generates multiple wavelengths, one at each reflection peak of the BFG.

In some embodiments the BFG can be formed by material growth or dielectric depositions in layers of alternating index of refraction in a plane perpendicular to the direction of light propagation. In this embodiment a phase shift is introduced by growing an extra thickness of a layer. This type of grating may be used in vertical cavity surface emitting lasers (VCSELs), for example.

In some embodiments the BFG can be formed as part of a laser cavity, underneath, above, or as part of an optical gain medium to form an active grating that both generates and reflects light.

In some embodiments two BFGs can be placed serially with a phase shift between them, or a BFG can have a phase shift added to it to form a distributed feedback (DFB) laser.

In some embodiments the phase shift locations within the BFG grating superstructures are specifically chosen to optimize a grating or laser performance parameter such as fabrication process tolerance, optical power distribution within the grating or laser, and/or tunability via heating of the grating.

In some embodiments, the BFG grating is formed by using photolithography followed by etching.

In some embodiments, the BFG grating is formed in a silicon layer.

In some embodiments, the BFG grating is formed in a silicon nitride layer.

In some embodiments, the BFG grating is formed in a silicon or silicon nitride layer that has a gain medium placed above the grating, forming a DFB laser.

In some embodiments, multiple phase shifts may be adjacent to each other, effectively creating a phase shift greater than π. The likelihood of this occurring increases as the number of phase shifts is increased in the design optimization process.

In some embodiments, the BFG comb spectrum can be synthesized with uneven spacings between reflection peaks. In this embodiment the superstructure length is chosen to be long enough to allow access to Fourier coefficients which are at frequencies an integer factor of the desired frequency shift. e.g. if comb lines are to be displaced by 10 GHz relative to a uniform comb spacing case (for example instead of 400 GHz uniform spacing, having 390 GHz, 410 GHz, etc.), the superstructure should allow for 10 GHz Fourier components to be supported. Similarly, if 50 GHz frequency shifts are desired, the superstructure length needs to be long enough to support these.

In some embodiments, the full BFG can be composed of dissimilar superstructures. In this case, the individual superstructures composing the full grating are optimized independently and therefore have phase shifts and differing locations. Each superstructure produces a comb-like spectrum, with reflections being located at different frequency positions and having identical amplitudes. However, the amplitudes of the side modes present in each superstructure's spectrum will vary as a result of the optimization process. By cascading these varying superstructures, the desired comb reflection peaks increase while the constructive effect of the addition of amplitudes for the side modes can be suppressed and therefore potentially allow for improved spectral characteristics to be attained. The positions of the comb lines can be chosen such that they follow an interleaved configuration, where superstructure A is made to reflect even integer comb lines at 0 GHz, 2Δ GHz, 4Δ GHz and so on, and superstructure B is made to reflect odd integer comb lines at 1Δ GHz, 3Δ GHz, and so on. Here A represents the nominal comb spacing bandwidth that is chosen for a particular design. Alternatively, in other embodiments, the positions of the comb lines can be chosen such they follow a sequential configuration, where superstructure A is made to reflect the set of closest N/G comb lines around the nominal Bragg wavelength, and superstructure B is made to reflect the set of N/G comb lines succeeding the first set. N being the total number of comb lines chosen for a design, and G being the number of separate blocks the comb should be split up into. Without loss of generality, the number of superstructures chosen can be extended beyond A&B as described above.

In some embodiments the UBB can instead have a length of the full final grating, and the grating modulation function repeats multiple times along the UBB to make multiple grating superstructures. The final binary Fourier grating structure and spectrum are equivalent to the approach described previously and in the claims in which multiple UBBs of length equal to the grating modulation function are cascaded serially.

In some embodiments the BFG can be optimized to have its cavity phase shifts or other aspects optimized to produce a specific desired electric field or photon density distribution along its length or to make a laser that has an asymmetric output power from its two sides. For example, all or most cavity phase shifts could be located only on one end of a DFB laser that uses a BFG grating.

In some embodiments the BFG is used in a DFB laser which may have multiple electrical contact sections along its length in order to facilitate different forward and/or reverse biases in different sections of the laser. This can be used to help distribute the electric field or photon density in a certain way, or to create saturable absorbers to enable mode locking or spectral broadening.

Various embodiments of a BFG and its methods of fabrication in accordance with the present disclosure may offer any one or more of the following advantages:
The synthesis process provides a means to obtain low-loss, high-reflectivity gratings;
Low loss as a result of requiring minimal amounts of perturbations (i.e. minimal phase shifts), resulting in a mostly regular, periodic structure that satisfies the Bragg condition almost everywhere;
High reflectivity as a result of the mostly unperturbed, entirely binary structure, which ensures the effective grating strength is maximized along the entire length of the grating;
The reflection strengths of all comb resonances are individually adjustable and thus can be made entirely flat, or can be made uneven, for example, to include gain-compensation;
The grating structure is optimally suited for fabrication due to its simple profile and highly periodic nature;
The superstructure-like design ensures a computationally tractable problem to solve;
The superstructure-like design ensures intrinsic comb spacing accuracy;
The superstructure-like design easily provides a method for synthesizing combs with uneven spacings;

It is to be understood that the present disclosure teaches only examples of embodiment in accordance with the present disclosures and that many variations of these embodiments can easily be devised by those skilled in the art after reading this disclosure and that the scope of the present invention is to be determined by the following claims;

1. A binary Fourier grating for producing a specified spectral response, comprising:
a plurality of grating superstructures disposed sequentially adjacent with respect to one another along a propagation direction of a light signal;
each of the grating superstructures having sequential sections with alternating refractive indices and one or more phase shift sections in which the refractive index does not alternate; and
wherein a location of the one or more phase shift sections determines reflections at specified wavelengths and suppression of reflections outside of the specified wavelengths and a length of the grating superstructure determines a wavelength spacing between the specified wavelengths to thereby produce the specified spectral response.

2. The binary Fourier grating of claim 1, wherein the specified wavelengths that are reflected define a wavelength comb.

3. The binary Fourier grating of claim 1, wherein all of the phase shifts in the grating superstructures are formed in high refractive index sections of the superstructure grating.

4. The binary Fourier grating of claim 1, wherein all of the phase shifts in the grating superstructures are formed in the low refractive index sections of the grating.

5. The binary Fourier grating of claim 1, wherein the phase shift are quarter wave phase shifts.

6. The binary Fourier grating of claim 1, wherein the phase shifts are distributed phase shifts.

7. The binary Fourier grating of claim 1, wherein a number of phase shifts within each of the grating superstructures is about twice the number of desired comb lines.

8. The binary Fourier grating of claim 1, further comprising a laser gain material that is part of a waveguide of the binary Fourier grating, together forming a distributed feedback laser.

9. A method of forming a binary Fourier-domain synthesized grating for generating a comb-like spectral reflection profile with adjustable comb line spacing, the method comprising:
defining a target spectral reflection profile having a plurality of comb lines at desired wavelengths and amplitudes;
selecting a uniform binary grating structure having a constant grating period corresponding to a Bragg wavelength of a specified comb line in the target spectral reflection profile and a length corresponding to a desired comb line spacing;
determining a set of phase-shift locations within the uniform binary grating structure, wherein each phase-shift location introduces a quarter-wave shift in the grating periodicity, the phase-shift locations being selected to match the target spectral reflection profile; and
incorporating the phase-shifts into the uniform binary grating structure at the selected phase-shift locations to thereby produce a grating superstructure; and
arranging a plurality grating superstructures adjacent sequentially with respect to one another along the propagation direction of a light signal to form the binary Fourier-domain synthesized grating.

10. The method of claim 9, wherein determining the set of phase-shift locations includes performing a Fourier domain analysis to select a modulation function that modulates and repeats the specified comb line to produce the target spectral reflection profile.

11. The method of claim 9, wherein at least 2 of the plurality of grating superstructures have a phase shift placed therebetween for producing a distributed feedback laser grating.

12. The method of claim 11, wherein the phase shift is a quarter wave phase shift.

13. The method of claim 11, wherein the phase shift is a distributed phase shift.

14. The method of claim 11, wherein multiple instances of the grating superstructures have phase shifts placed therebetween.

15. The method of claim 9, wherein one or more grating superstructures includes therein a phase shift for producing a distributed feedback laser grating.

16. The method of claim 15, wherein the phase shift is a distributed phase shift for producing a distributed feedback laser grating.

17. The method of claim 15, wherein the grating superstructure includes a plurality of phase shifts for producing a distributed feedback laser grating.

18. The method of claim 9, wherein a number of phase shifts within each of the grating superstructures is about twice the number of desired comb lines.

19. The method of claim 9, further comprising specifying at least some of locations of the phase shifts within each grating superstructure to optimize at least one of fabrication tolerance, optical power distribution within the grating, and wavelength tunability via localized heating.
